(19) United States
(12) Patent Application Publication
(10) Pub. No.: US 2025/0337216 A1
(43) Pub. Date: Oct. 30, 2025

(54) LASER BEAM EMITTING DEVICE AND OPTICAL MODULE

(71) Applicant: Mitsubishi Electric Corporation, Tokyo (JP)

(72) Inventors: Mizuki SHIRAO, Tokyo (JP); Takuma FUJITA, Tokyo (JP); Hiroshi MIURA, Tokyo (JP)

(73) Assignee: Mitsubishi Electric Corporation, Tokyo (JP)

(21) Appl. No.: 19/259,012

(22) Filed: Jul. 3, 2025

Related U.S. Application Data
(63) Continuation of application No. PCT/JP2023/009476, filed on Mar. 13, 2023.

(51) Int. Cl. H01S 5/0239; H01S 5/12

(52) U.S. Cl. CPC H01S 5/0239; H01S 5/12

(57) ABSTRACT

A laser beam emitting device includes: a substrate; a laser light source to generate a laser beam, the laser light source being held on a front surface of the substrate; a modulation unit to modulate the laser beam generated by the laser light source and emit the laser beam toward a predetermined direction from one end side of the substrate in the predetermined direction along the front surface of the substrate, the modulation unit being held on the front surface of the substrate; and a signal line to transmit to the modulation unit a modulated signal for modulating the laser beam generated by the laser light source, the signal line being formed on the front surface of the substrate, and the signal line is disposed at a position closer to the one end side than another end side of the substrate.

### CROSS REFERENCE TO RELATED APPLICATION

This application is a Continuation of PCT International Application No. PCT/JP2023/009476, filed on Mar. 13, 2023, which is hereby expressly incorporated by reference into the present application.

### TECHNICAL FIELD

The present disclosure relates to a laser beam emitting device and an optical module.

### BACKGROUND ART

Conventionally, there has been disclosed an optical module that includes a laser diode that outputs a laser beam, a semiconductor optical modulator that modulates and emits the laser beam, and a carrier that holds a semiconductor integrated photonic element (laser beam emitting device) that includes the laser diode and the semiconductor optical modulator (see Patent Literature 1). This optical module includes on a main surface of the carrier made of an insulator the semiconductor integrated photonic element, and a signal line that guides a modulated signal to the semiconductor integrated photonic element. Furthermore, this signal line is formed extending in a longitudinal direction of the carrier and from a position close to one end surface to a position close to the other end surface of the carrier.

### CITATION LIST

### Patent Literature

Patent Literature 1: JP 2018-74057 A

### SUMMARY OF INVENTION

### Technical Problem

The semiconductor integrated photonic element described in Patent Literature 1 has a problem that a modulated signal transmitted by resonance of the signal line may deteriorate depending on the frequency of the modulated signal to be input to the semiconductor optical modulator.

The present disclosure has been made to solve the above problem, and an object of the present disclosure is to provide a laser beam emitting device and an optical module that can suppress deterioration of a modulated signal to be transmitted.

### Solution to Problem

A laser beam emitting device according to the present disclosure includes: a modulator including a laser light source to generate a laser beam and a modulation device to modulate the laser beam generated by the laser light source and emit the laser beam toward one side of a predetermined direction; a substrate to hold the modulator on a front surface of the substrate; and a signal line to transmit a modulated signal for modulating the laser beam generated by the laser light source to the modulation device, wherein the signal line is disposed at a position closer to the one end side than another end side of the substrate, and the modulated signal is input from the one end side, and the signal line is formed on a front side and a back side of the substrate continuously.

### Advantageous Effects of Invention

According to the present disclosure, it is possible to shorten a signal line through which a modulated signal is transmitted compared to a conventional technology, so that it is possible to suppress resonance of the signal line and suppress deterioration of the modulated signal.

### BRIEF DESCRIPTION OF DRAWINGS

FIG. 1 is a perspective view illustrating an optical module according to Embodiment 1 and seen from a front surface side.

FIG. 2 is a perspective view illustrating the optical module according to Embodiment 1 and seen from a back surface side.

FIG. 3 is an enlarged view illustrating the optical module according to Embodiment 1.

FIG. 4 is a perspective view illustrating a laser beam emitting device according to Embodiment 1 and seen from the front surface side.

FIG. 5 is a perspective view illustrating the laser beam emitting device according to Embodiment 1 and illustrating the front surface side seen from a direction different from that in FIG. 4.

FIG. 6 is a graph showing comparison results of an S21 characteristic simulation based on differences in signal line length according to Embodiment 1.

FIG. 7 is a perspective view illustrating a laser beam emitting device according to Embodiment 2 and seen from a front surface side.

FIG. 8 is a perspective view illustrating the laser beam emitting device according to Embodiment 2 and seen from a back surface side.

FIG. 9 is a perspective view illustrating an optical module according to Embodiment 3 and seen from a front surface side.

FIG. 10 is a perspective view illustrating an optical module according to Embodiment 4 and seen from a front surface side.

FIG. 11 is a perspective view illustrating the optical module according to Embodiment 4 and seen from a back surface side.

### DESCRIPTION OF EMBODIMENTS

Embodiments according to the present disclosure will be described in detail below with reference to the drawings.

### Embodiment 1

First, a schematic configuration of an optical module 1 according to

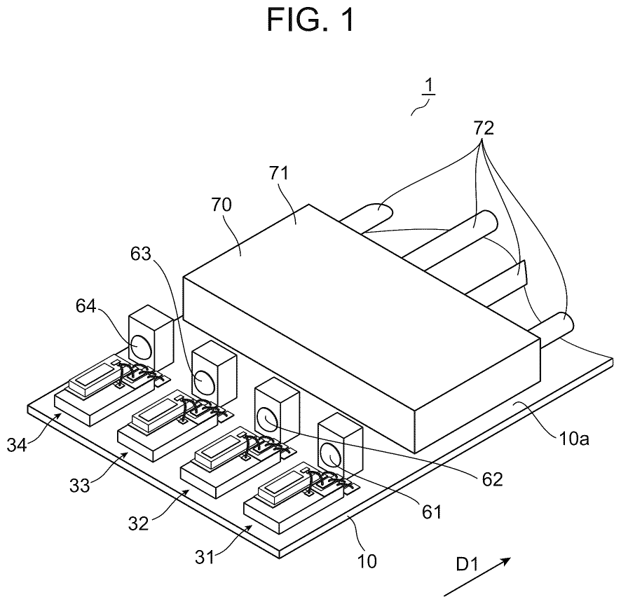

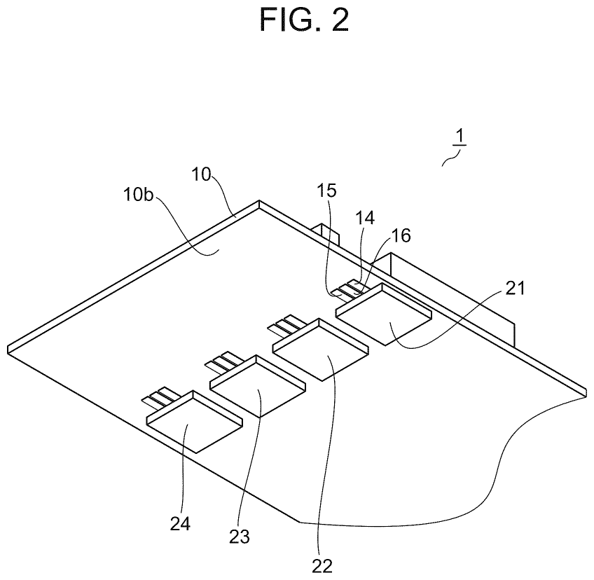

Embodiment 1 will be described with reference to FIGS. 1 to 3. FIG. 1 is a perspective view illustrating the optical module 1 according to Embodiment 1 and seen from a front surface side, and FIG. 2 is a perspective view illustrating the optical module 1 according to Embodiment 1 and seen from a back surface side. The optical module 1 according to Embodiment 1 is a module that converts an electrical signal into an optical signal, and outputs the optical signal via an optical fiber. As illustrated in FIGS. 1 and 2, the optical module 1 according to Embodiment 1 includes a module substrate 10, drive circuits 21, 22, 23, and 24 that are a plurality of drive circuits, laser beam emitting devices 31, 32, 33, and 34 that are a plurality of laser beam emitting devices, condenser lenses 61, 62, 63, and 64 that are a plurality of condenser lenses, a fiber array 70, various wirings, and the like.

The module substrate 10 that is a second substrate is formed in a plate shape using an insulation material, and holds each component of the optical module 1. For example, the module substrate 10 is formed using a synthetic resin, ceramics such as aluminum nitride, or a combination thereof, and may be formed using Low Temperature Co-fired Ceramics (LTCC) or the like.

The drive circuits 21 to 24 that are modulated signal output units are held on the module substrate 10, and output modulated signals to the corresponding laser beam emitting devices. For example, the drive circuits 21 to 24 are held on a back surface 10b of the module substrate 10, and generate modulated signals that are electrical signals to be output to an EML. More specifically, the drive circuit includes a signal amplifier, a digital signal processing circuit, or the like.

The laser beam emitting devices 31, 32, 33, and 34 modulate and emit laser beams on the basis of the modulated signals from the corresponding drive circuits among the drive circuits 21 to 24. For example, the laser beam emitting devices 31 to 34 are held on a surface opposite to the surface of the module substrate 10 on which the drive circuits 21 to 24 are held. In other words, the laser beam emitting devices 31 to 34 are held on a front surface 10a of the module substrate 10. More specifically, the laser beam emitting devices 31 to 34 are held on the front surface 10a of the module substrate 10 in a state where the laser beam emitting devices 31 to 34 are aligned and disposed at pitches equal to or less than one mm. Furthermore, for example, each of the laser beam emitting devices 31 to 34 emits a laser beam in a D1 direction that is a predetermined direction along the front surface 10a of the module substrate 10 and is illustrated in FIG. 1. Note that, in the following description, a direction perpendicular to the D1 direction among directions along the front surface 10a of the module substrate 10 will be referred to as a lateral direction, and a direction perpendicular to the front surface 10a of the module substrate 10 will be referred to as an upper/lower direction. Details of the laser beam emitting devices 31 to 34 will be described later.

The condenser lenses 61, 62, 63, and 64 are optically connected with the laser beam emitting devices 31 to 34, and condense the laser beams from the corresponding laser beam emitting devices among the laser beam emitting devices 31 to 34 and output the condensed laser beams to the fiber array 70. For example, the condenser lenses 61 to 64 are held on the front surface 10a of the module substrate 10, are disposed closer to a front (downstream) in the D1 direction than the laser beam emitting devices 31 to 34, and are disposed facing the corresponding laser beam emitting devices among the laser beam emitting devices 31 to 34. The condenser lenses 61 to 64 condense the laser beams that are emitted from the laser beam emitting devices 31 to 34 and travel in free space while widening. In other words, the condenser lenses 61 to 64 convert, into condensed beams, the laser beams that are emitted from the laser beam emitting devices 31 to 34 and travel in free space while widening.

The fiber array 70 is optically connected with the condenser lenses 61 to 64, and outputs the laser beams from the condenser lenses 61 to 64 to an unillustrated external device or the like. For example, the fiber array 70 includes an optical system 71 and optical fibers 72. For example, the fiber array 70 is held on the front surface 10a of the module substrate 10, and is disposed closer to the front in the D1 direction than the condenser lenses 61 to 64. For example, the optical system 71 includes an unillustrated lens, mirror, multiplexer, demultiplexer, and the like.

The optical fiber 72 transmits a laser beam from the optical system 71 to an unillustrated external device. For example, the optical fibers 72 have mode field diameters that are four to five times as long as those of the laser beam emitting devices 31 to 34, and are disposed in such a way that distances from the condenser lenses 61 to 64 to the optical fiber 72 are four to five times as long as distances from the laser beam emitting devices 31 to 34 to the condenser lenses 61 to 64. More specifically, the condenser lenses 61 to 64 are disposed at approximately 200 um close to the laser beam emitting devices 31 to 34 to sufficiently take in the laser beams of the laser beam emitting devices 31 to 34, and the optical fibers 72 are disposed in such a way that the distances from the optical fibers 72 to the condenser lenses 61 to 64 are approximately 800 um to 1 mm.

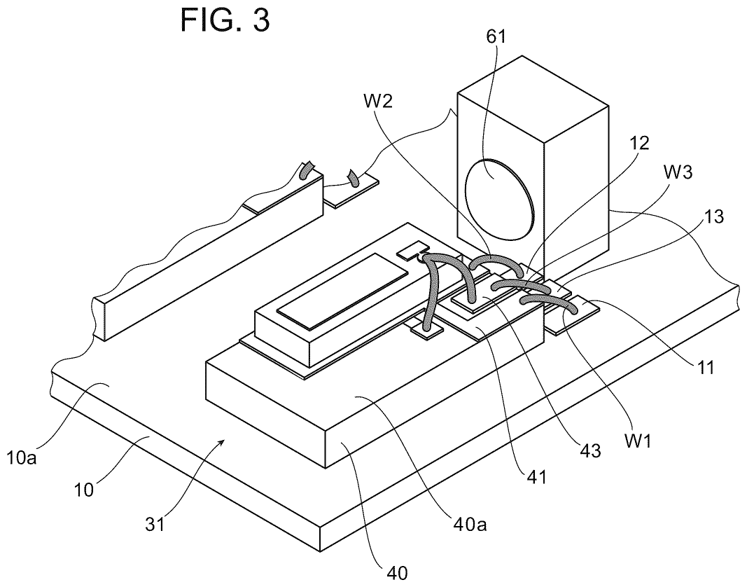

FIG. 3 is an enlarged view illustrating the optical module 1 according to Embodiment 1. As illustrated in FIGS. 2 and 3, the optical module 1 includes wirings 14, 15, and 16, wirings 11, 12, and 13, and wirings W1, W2, and W3 that transmit modulated signals from the drive circuits 21 to 24 to the laser beam emitting devices 31 to 34. Note that, since configurations of the drive circuits 22 to 24 and the laser beam emitting devices 32 to 34 of the optical module 1 are the same as configurations of the drive circuit 21 and the laser beam emitting device 31, the configurations of the drive circuit 21 and the laser beam emitting device 31 will be described, and description of the configurations of the drive circuits 22 to 24 and the laser beam emitting devices 32 to 34 will be omitted.

Each of the wirings 14 to 16 is electrically connected with each terminal of the drive circuit 21. For example, the wiring 14 and the wiring 15 are electrically connected with a ground terminal of the drive circuit 21, and the wiring 16 is electrically connected with a signal terminal of the drive circuit 21 to transmit modulated signals. Furthermore, for example, the wirings 14 to 16 extend in a direction along the front surface 10a of the module substrate 10, and are formed on the back surface 10b. Furthermore, for example, the wirings 14 to 16 are formed using a conductive metal film.

The wirings 11 to 13 are electrically connected with the wirings 14 to 16, respectively. For example, the wiring 11 and the wiring 12 are electrically connected with the ground terminal of the drive circuit 21 via the wiring 14 and the wiring 15, and the wiring 13 is electrically connected with the signal terminal of the drive circuit 21 via the wiring 16 to transmit modulated signals. Furthermore, for example, the wirings 11 to 13 extend in the direction along the front surface 10a of the module substrate 10, and are formed on the front surface 10a. Furthermore, for example, the wirings 11 to 13 are electrically connected with the wirings 14 to 16, respectively, by unillustrated vias formed along the upper/lower direction. Furthermore, for example, the wirings 11 to 13 are formed using a conductive metal film.

Each of the wirings 11 to 13 electrically connects each of the wirings 11 to 13 and the laser beam emitting device 31. For example, the wiring W1 and the wiring W2 are electrically connected with the ground terminal of the drive circuit 21 via the wiring 11 and the wiring 12, and the wiring W3 is electrically connected with the signal terminal of the drive circuit 21 via the wiring 13 to transmit modulated signals. Furthermore, for example, each of the wirings W1 to W3 is formed using a conductive metal wire, and connects each of the wirings 11 to 13 and the laser beam emitting device 31 by wire bonding. More specifically, the wirings W1 to W3 are formed using gold wires.

As described above, the optical module 1 is configured as a 4ch optical module that includes the four drive circuits, four laser beam emitting devices, the four condenser lenses, and the fiber array, and converts a modulated signal that is an electrical signal into an optical signal and outputs the optical signal through the optical fiber. For example, the optical module 1 is configured to have a total transmission capacity of 800 Gbps by causing the four laser beam emitting devices to operate by the 100 GBaud-PAM4. Note that the numbers of the drive circuits, the laser beam emitting devices, and the condenser lenses are not limited to four, and may be one or may be numbers equal to or more than two other than four.

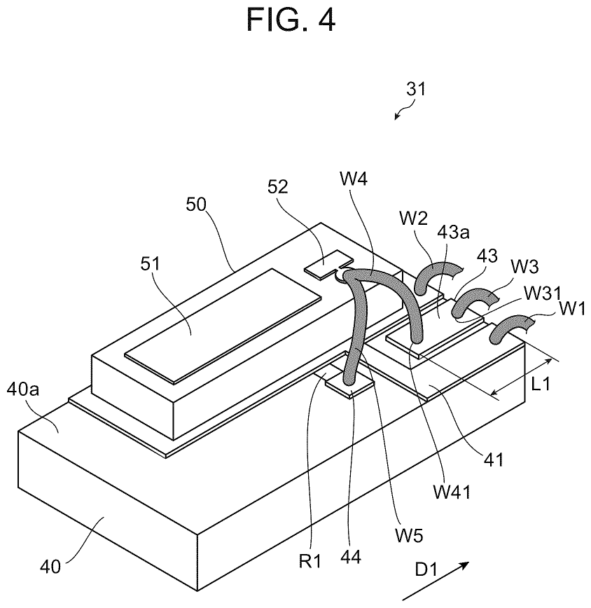

Next, details of the configuration of the laser beam emitting device 31 will be described with reference to FIGS. 4 to 6. Note that, since the configurations of the laser beam emitting devices 32 to 34 are the same as the configuration of the laser beam emitting device 31, the configuration of the laser beam emitting device 31 will be described and description of the configurations of the laser beam emitting devices 32 to 34 will be omitted.

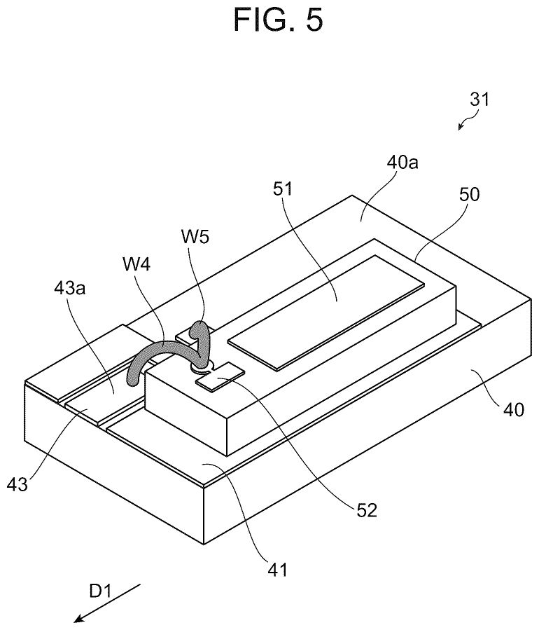

FIG. 4 is a perspective view illustrating the laser beam emitting device 31 according to Embodiment 1 and seen from a front surface 40a side, and FIG. 5 is a perspective view illustrating the laser beam emitting device 31 according to Embodiment 1 and illustrating the front surface 40a side seen from a direction different from that in FIG. 4. As illustrated in FIGS. 4 and 5, the laser beam emitting device 31 includes a substrate 40 that is a first substrate, a wiring 41, a wiring 43, a wiring 44, a wiring W4, a wiring W5, an Electro-absorption Modulator Laser (EML) 50, and a terminating resistance R1.

The substrate 40 is formed in a plate shape using an insulation material, and holds each component of the laser beam emitting device 31. For example, the substrate 40 is formed in a plate shape along the D1 direction in which the module substrate 10 extends, and is held on the front surface 10a of the module substrate 10. More specifically, the substrate 40 is formed in a plate shape in which the length in the D1 direction is longer than the length in the lateral direction, and is held on the front surface 10a of the module substrate 10. Furthermore, for example, the substrate 40 is formed using a synthetic resin, ceramics such as aluminum nitride, or a combination thereof, and may be formed using Low Temperature Co-fired Ceramics (LTCC) or the like.

The wiring 41 and the wiring 43 are electrically connected with the wirings W1 to W3. For example, the wiring 41 is electrically connected with the ground terminal of the drive circuit 21 via the wiring W1 and the wiring W2, and the wiring 43 is electrically connected with the signal terminal of the drive circuit 21 via the wiring W3 to transmit modulated signals. Furthermore, for example, the wiring 41 and the wiring 43 extend in the direction along the front surface 40a of the module substrate 40, and are formed on the front surface 40a. Furthermore, for example, the wiring 41 and the wiring 43 are formed using a conductive metal film.

The EML 50 includes a laser light source 51 that receives supply of electrical power and generates a laser beam, and modulates and emits the laser beam generated by the laser light source 51. For example, the EML 50 is held on the front surface 40a of the substrate 40 with the wiring 41 interposed therebetween by soldering or the like. For example, the laser light source 51 is formed as a Distributed FeedBack-Laser Diode (DFB-LD). Furthermore, for example, the laser light source 51 is formed in such a way that the length in the D1 direction that is a longitudinal direction of the laser light source 51 is approximately 500 um.

The modulation unit 52 modulates the laser beam generated by the laser light source 51 on the basis of the modulated signal from the drive circuit 21. For example, the modulation unit 52 is disposed closer to the front in the D1 direction than the laser light source 51. Furthermore, for example, the modulation unit 52 modulates the intensity of the laser beam generated by the laser light source 51 on the basis of a change of the voltage of the modulated signal from the drive circuit 21, and emits the modulated laser beam toward the D1 direction from one end side of the substrate 40 in the D1 direction along the front surface 40a of the substrate 40. For example, the modulation unit 52 is configured by an Electro-Absorption Modulator (EAM). Furthermore, for example, the modulation unit 52 is formed in such a way that the length in the D1 direction is approximately 100 um smaller than the laser light source 51 to reduce a parasitic capacitance.

The terminating resistance R1 electrically connects the wiring 44 and the wiring 41, and terminates the modulated signal from the drive circuit 21. For example, the terminating resistance R1 is held on the front surface 40a of the substrate 40, and the wiring 44 is formed on the front surface 40a of the substrate 40.

The wiring W4 electrically connects the wiring 43 and the modulation unit 52. For example, the wiring W4 is formed using a conductive metal wire, and connects the wiring 43 and the modulation unit 52 by wire bonding. More specifically, the wiring W4 is formed using a gold wire. The wiring W5 electrically connects the wiring 44 and the modulation unit 52. For example, the wiring W5 is formed using a conductive metal wire, and connects the wiring 44 and the modulation unit 52 by wire bonding. More specifically, the wiring W5 is formed using a gold wire.

Generally, when a high frequency signal transmits through a long wiring, the wiring resonates, and therefore a signal to be transmitted may deteriorate. The laser beam emitting device 31 according to Embodiment 1 includes the wiring 43 that is the signal line for transmitting a modulated signal and is disposed at a position closer to an end side in the D1 direction than an end side in a direction opposite to the D1 direction of the substrate 40 to suppress the length of the wiring 43 and suppress resonance of the wiring 43. In other words, in the laser beam emitting device 31 according to Embodiment 1, the modulation unit 52 emits a laser beam from the one end side of the substrate 40, and the wiring 43 is disposed at a position closer to one end side than the other end side of the substrate 40 to suppress the length of the wiring 43 and suppress resonance of the wiring 43.

For example, the wiring 43 and the modulation unit 52 are disposed closer to the end side of the substrate 40 in the D1 direction than the center in the D1 direction of the substrate 40. Furthermore, for example, the wiring 43 includes a specific transmission part 43a that transmits the modulated signal along the direction opposite to the D1 direction. In other words, the wiring 43 is formed in such a way that the modulated signal is input in the direction opposite to the D1 direction. Furthermore, for example, the wiring 43 is formed in such a way that a connection part W31 with the wiring W3 is formed so as to be located closer to the front in the D1 direction than a connection part W41 with the wiring W4. Furthermore, for example, the wiring 43 is formed in such a way that a connection part W31 with the wiring W3 and the connection part W41 with the wiring W4 are both formed so as to be located closer to the front in the D1 direction than the laser light source 51. Furthermore, for example, the wiring 43 is formed long in the D1 direction. Furthermore, for example, the wiring 43 is formed in such a way that an end side in the D1 direction of the wiring 43 is close to an end side in the D1 direction of the substrate 40.

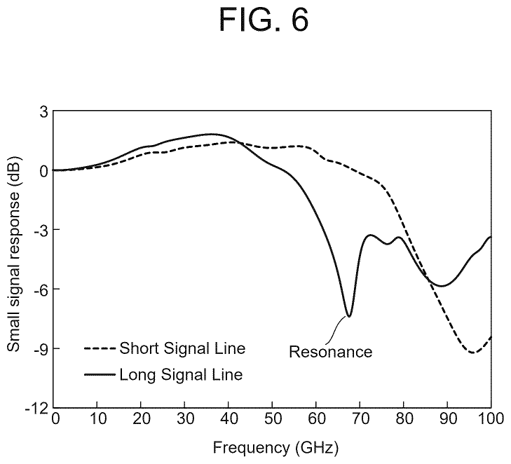

FIG. 6 is a graph showing S21 characteristics simulation results of the laser beam emitting device 31 according to Embodiment 1, and the laser beam emitting device whose length of the wiring 43 as the signal line is longer than that of the laser beam emitting device 31. In FIG. 6, the result of the laser beam emitting device 31 including the wiring 43 according to Embodiment 1 is indicated by a broken line, and the result of the laser beam emitting device whose length of the wiring corresponding to the wiring 43 is longer than that of the laser beam emitting device 31 is indicated by a solid line. Simulation was conducted assuming that the length of the wiring 43 of the laser beam emitting device 31 is 300 um, and the length of the wiring of the laser beam emitting device whose length of the wiring corresponding to the wiring 43 is longer than that of the laser beam emitting device 31 is 800 um. It is found that, while the laser beam emitting device whose length of the wiring is long resonates at around 67 GHz, the laser beam emitting device 31 according to Embodiment 1 is suppressed from resonating, and characteristics in a 3 dB band improve.

As described above, the laser beam emitting device 31 according to Embodiment 1 includes the substrate 40, the laser light source 51 that is held on the front surface 40a of the substrate and generates laser light, the modulation unit 52 that is held on the front surface 40a of the substrate 40, and modulates the laser beam generated by the laser light source and emits the laser beam toward the D1 direction from the one end side of the substrate 40 in the D1 direction along the front surface 40a of the substrate 40, and the wiring 43 that is formed on the front surface 40a of the substrate 40, and transmits to the modulation unit 52 a modulated signal for modulating the laser beam generated by the laser light source, and the wiring 43 is disposed at the position closer to the one end side than the other end side of the substrate 40.

The laser beam emitting device 31 according to Embodiment 1 is configured as described above, and consequently can shorten the wiring 43 for transmitting a modulated signal compared to the conventional technology. For example, the laser beam emitting device 31 can shorten the length of a transmission route of a signal of the wiring 43 for transmitting a modulated signal compared to the conventional technology. Furthermore, for example, the laser beam emitting device 31 can shorten a length L1 (see FIG. 4) in the D1 direction of the wiring 43 for transmitting a modulated signal compared to the conventional technology. Consequently, by setting a higher frequency than a frequency of a signal at which a resonance frequency of the wiring 43 transmits, the laser beam emitting device 31 according to Embodiment 1 can suppress resonance of the wiring 43 and suppress deterioration of the modulated signal. Furthermore, by suppressing deterioration of the modulated signal, the laser beam emitting device 31 according to Embodiment 1 can obtain a good optical waveform at a time of high Baud rate modulation that is promising as a modulation method of next-generation Ethernets, and for which a band exceeding 60 GHz such as the 100 GBaud-PAM4 is demanded.

Furthermore, the optical module 1 according to Embodiment 1 includes the module substrate 10, the laser beam emitting device 31 that is held on the module substrate 10, and the drive circuit 21 that is held on the module substrate 10 and outputs a modulated signal for modulating the laser beam generated by the laser light source 51, and the drive circuit 21 is held on the surface opposite to the surface 10a of the module substrate 10 on which the laser beam emitting device 31 is held. The optical module 1 is configured as described above, and consequently can effectively utilize the front surface 10a and the back surface 10b of the module substrate 10, and improve the degrees of density of the parts and the wirings on the front surface 10a.

Note that, in Embodiment 1, the optical module 1 is configured in such a way that laser beams from the laser beam emitting devices 31 to 34 are input to the fiber array via the condenser lenses 61 to 64, yet is not limited to this. An optical module only needs to be configured to be able to transmit laser beams emitted from laser beam emitting devices to an external device or the like, and may include, for example, a Planar Lightwave Circuits (PLC) or a silicon photonics integrated circuit and be configured in such a way that the laser beams emitted from the laser beam emitting devices are input to this PLC or silicon photonics integrated circuit. In a case where the optical module is configured as described above, the optical module can be applied to the WDM system by using the PLC or the silicon photonics integrated circuit having a wavelength multiplexing function.

Furthermore, in Embodiment 1, the drive circuits 21 to 24 are held on the surface opposite to the surface of the module substrate 10 on which the laser beam emitting devices 31 to 34 are held yet is not limited to this. The drive circuits only need to be electrically connected with the laser beam emitting devices, and may be held on the surface of the module substrate on which the laser beam emitting devices are held.

Furthermore, in Embodiment 1, the wiring 43 is formed longer in the D1 direction, and disposed closer to the end side of the substrate 40 in the D1 direction than the center in the D1 direction of the substrate 40, yet is not limited thereto. The wiring 43 only needs to be formed in such a way that the wiring 43 is disposed at the position closer to the end side in the D1 direction than the end side in the opposite direction to the D1 direction of the substrate 40 so as to make it possible to shorten the length for transmitting signals compared to the conventional technology, for example, the wiring 43 may be formed in such a way that the length in the lateral direction is longer than that in the D1 direction, may be formed in such a way that part of the wiring 43 is located closer to a side opposite to the D1 direction than the center in the D1 direction of the substrate 40, the connection part W31 with the wiring W3 may be formed so as to be located in the lateral direction of the connection part W41 with the wiring W4, may be formed to transmit a modulated signal along the lateral direction, or may be disposed in such a way that part of the wiring 43 is disposed closer to the end side in the lateral direction of the substrate 40.

Furthermore, in Embodiment 1, the wirings 11 to 13 are formed on the front surface 10a of the module substrate 10, and the wirings 14 to 16 are formed on the back surface 10b of the module substrate 10, yet are not limited thereto. These wirings only need to be formed so as to electrically connect the drive circuits 21 to 24 and the laser beam emitting devices 31 to 34, for example, the wirings 11 to 13 may be formed on the back surface 10b of the module substrate 10, the wirings 14 to 16 may be formed on the front surface 10a of the module substrate 10, the wirings 11 to 13 and the wirings 14 to 16 may be formed on one of the front surface 10a and the back surface 10b of the module substrate 10, and unillustrated other wirings may be formed between the wirings 11 to 13 and the wirings 14 to 16. Furthermore, in a case where the module substrate is formed as a multilayer substrate, the wirings 11 to 13 and the wirings 14 to 16 may be partially or entirely formed on an inner layer of the module substrate.

Furthermore, in Embodiment 1, the wirings 41, 43, and 44 are formed on the front surface 40a of the substrate 40, yet are not limited thereto. These wirings only need to be formed so as to electrically connect the drive circuits 21 to 24, the laser light source 51, the modulation unit 52, and the terminating resistance R1, for example, the wirings 41, 43, and 44 may be partially formed on a back surface 40b of the module substrate 40, or may be partially formed on the side surface that connects the front surface 10a and the back surface 40b of the substrate 40. Furthermore, in a case where the substrate for the laser beam emitting devices is formed as a multilayer substrate, the wirings 41, 43, and 44 may be partially or entirely formed on an inner layer of the multilayer substrate.

Furthermore, in Embodiment 1, the optical module 1 is configured in such a way that the laser beam emitting device 31 and the wirings 11 to 13 formed on the module substrate 10 are connected by wire bonding, yet is not limited to this. The optical module only needs to be configured to electrically connect the laser beam emitting devices and the drive circuits, and may be configured to electrically connect the laser beam emitting devices and the drive circuits by, for example, bringing the wirings formed on the surface of the substrate for the laser beam emitting devices, and the wirings formed on the surface of the module substrate into contact.

### Embodiment 2

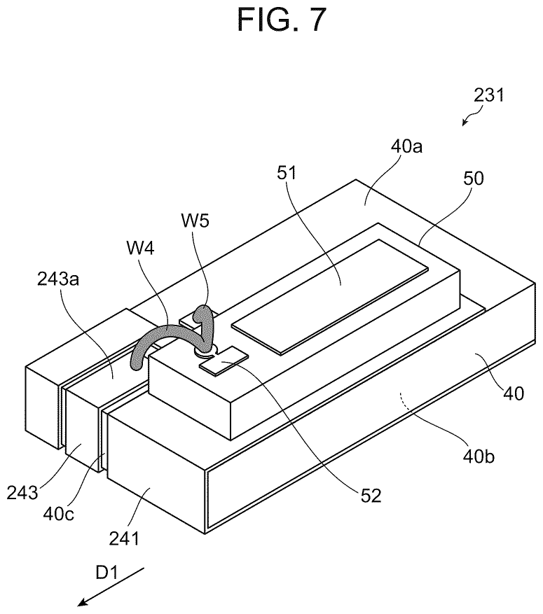

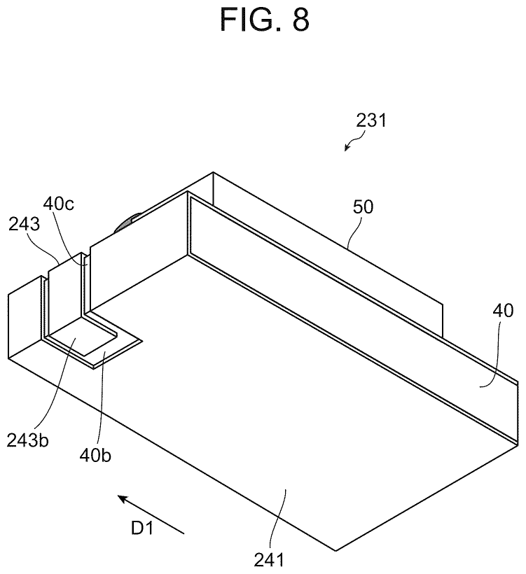

Next, a laser beam emitting device 231 according to Embodiment 2 will be described with reference to FIGS. 7 and 8. Upon comparison between the laser beam emitting device 231 according to Embodiment 2 and the laser beam emitting devices 31 to 34 according to Embodiment 1, wirings formed on the substrate 40 are different, yet the other components are the same, the same components as those in Embodiment 1 will be assigned the same reference numerals, and description thereof will be omitted.

FIG. 7 is a perspective view illustrating the laser beam emitting device 231 according to Embodiment 2 and seen from the front surface 40a side, and FIG. 8 is a perspective view illustrating the laser beam emitting device 231 according to Embodiment 2 and seen from the back surface 40b side. As illustrated in FIGS. 7 and 8, the laser beam emitting device 231 includes the substrate 40, a wiring 241, a wiring 243, the wiring 44 (see FIG. 4), the wiring W4, the wiring W5, the EML 50, and the terminating resistance R1 (see FIG. 4).

The wiring 241 and the wiring 243 are electrically connected with the wirings 11 to 13 (see FIG. 3). For example, the wiring 241 is formed over the front surface 40a of the substrate 40, a side surface 40c of the substrate 40, and the back surface 40b of the substrate, and, when a part of the wiring 241 formed on the back surface 40b of the substrate contacts the wiring 11 and the wiring 12, the wiring 241 is electrically connected with the wiring 11 and the wiring 12. More specifically, the wiring 241 is formed over the front surface 40a of the substrate 40, the side surface 40c in the D1 direction of the substrate 40, and the back surface 40b of the substrate, and, when a part of the wiring 241 formed on the back surface 40b of the substrate contacts the wiring 11 and the wiring 12, the wiring 241 is electrically connected with the wiring 11 and the wiring 12. For example, the wiring 241 is formed using a conductive metal film.

Furthermore, for example, the wiring 243 is formed over the front surface 40a of the substrate 40, the side surface 40c of the substrate 40, and the back surface 40b of the substrate, and, when a part of the wiring 243 formed on the back surface 40b of the substrate contacts the wiring 13, the wiring 243 is electrically connected with the wiring 13. More specifically, the wiring 243 is formed over the front surface 40a of the substrate 40, the side surface 40c in the D1 direction of the substrate 40, and the back surface 40b of the substrate, and, when a part of the wiring 243 formed on the back surface 40b of the substrate contacts the wiring 13, the wiring 243 is electrically connected with the wiring 13. For example, the wiring 243 includes a specific transmission part 243a that transmits a modulated signal along the direction opposite to the D1 direction, and a specific transmission part 243b that transmits a modulated signal along the D1 direction. Furthermore, for example, the wiring 243 is formed using a conductive metal film.

Note that, in a case where the laser beam emitting devices are configured as in Embodiment 2, it is required that the optical module is configured in such a way that a signal wiring and a ground wiring can be electrically isolated by, for example, forming a metal bump on at least one of the back surface of the substrate for the laser beam emitting devices, and the front surface of the module substrate.

Furthermore, in Embodiment 2, the wiring 241 and the wiring 243 are formed on the front surface 40a, the side surface 40c in the D1 direction, and the back surface 40b of the substrate 40, yet are not limited thereto. The wiring 241 and the wiring 243 only need to be formed so as to be electrically connected with the wirings 11 to 13, and, for example, the wiring 241 and the wiring 243 may be formed on the front surface 40a of the substrate 40 and the side surface of the substrate 40, may be formed on the front surface 40a of the substrate 40, and the side surface in the lateral direction and the back surface 40b of the substrate 40, and, parts of the wiring 241 and the wiring 243 formed on the front surface 40a of the substrate 40 and parts of the wiring 241 and the wiring 243 formed on the back surface 40b may be formed so as to be electrically connected by vias formed along the upper/lower direction. Furthermore, the optical module may be configured in such a way that the drive circuits and the laser devices are held on the front surface 10a of the module substrate 10, the drive circuits are disposed closer to a rear in the D1 direction than the laser beam emitting devices, and, when parts formed on the back surface of the substrate for the laser beam emitting devices, and each terminal of the drive circuits contact the wirings formed on the front surface of the module substrate, the laser beam emitting devices and the drive circuits are electrically connected.

### Embodiment 3

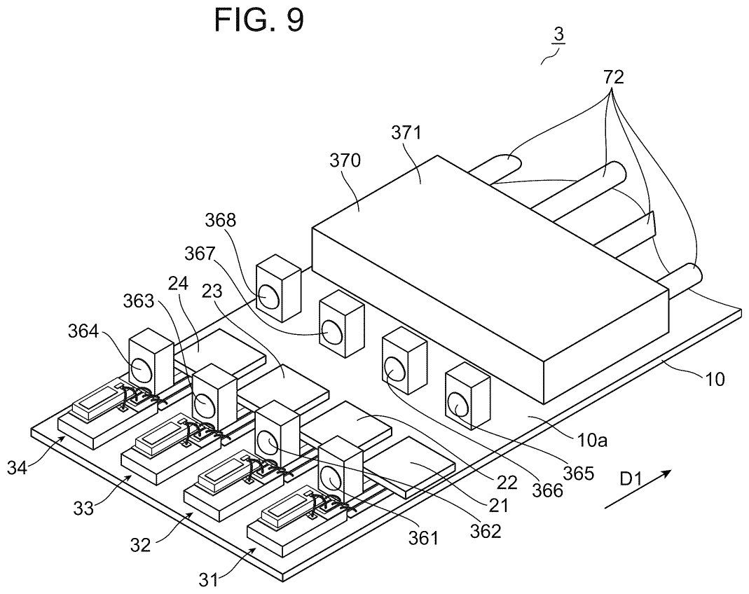

Next, an optical module 3 according to Embodiment 3 will be described with reference to FIG. 9. Upon comparison between the optical module 3 according to Embodiment 3 and the optical module 1 according to Embodiment 1, wirings formed on the module substrate 10, arrangement of the drive circuits 21 to 24, and components related to routes of laser beams from the laser beam emitting devices 31 to 34 to the optical fibers 72 are different, yet the other components are the same, and the same components as those in Embodiment 1 will be assigned the same reference numerals, and description thereof will be omitted.

FIG. 9 is a perspective view illustrating the optical module 3 according to Embodiment 3 and seen from the front surface 10a side. As illustrated in FIG. 9, the optical module 3 includes the module substrate 10, the drive circuits 21 to 24, the laser beam emitting devices 31 to 34, collimating lenses 361, 362, 363, and 364, condenser lenses 365, 366, 367, and 368, a fiber array 370, various wirings, and the like.

The drive circuits 21 to 24 are held on the front surface 10a of the module substrate 10 on which the laser beam emitting devices 31 to 34 are held. For example, the drive circuits 21 to 24 are disposed closer to the front in the D1 direction than the laser beam emitting devices 31 to 34. More specifically, the drive circuits 21 to 24 are disposed closer to the front in the D1 direction than the laser beam emitting devices 31 to 34, and are electrically connected with the laser beam emitting devices 31 to 34 by wirings formed on the front surface 10a.

The collimating lenses 361 to 364 that are parallel beam conversion units are optically connected with the laser beam emitting devices 31 to 34, convert the laser beams from the corresponding laser beam emitting devices among the laser beam emitting devices 31 to 34 into parallel beams, and output the converted parallel beams to the condenser lenses 365 to 368. For example, the collimating lenses 361 to 364 are held on the front surface 10a of the module substrate 10, are disposed between the laser beam emitting devices 31 to 34 and the drive circuits 21 to 24 in the D1 direction, and are disposed facing the corresponding laser beam emitting devices among the laser beam emitting devices 31 to 34.

The condenser lenses 365 to 368 are optically connected with the collimating lenses 361 to 364, condense the laser beams that are parallel beams from the corresponding collimating lenses among the collimating lenses 361 to 364, and output the condensed laser beams to the fiber array 370. For example, the condenser lenses 365 to 368 are held on the front surface 10a of the module substrate 10, and are disposed closer to the front in the D1 direction than the collimating lenses 361 to 364. More specifically, the condenser lenses 365 to 368 are held on the front surface 10a of the module substrate 10, and are disposed closer to the front in the D1 direction than the drive circuit 21 to 24.

The fiber array 370 is optically connected with the condenser lenses 365 to 368, and outputs the laser beams from the condenser lenses 365 to 368 to an unillustrated external device or the like. For example, the fiber array 370 includes an optical system 371 and the optical fibers 72. For example, the fiber array 70 is held on the front surface 10a of the module substrate 10, and is disposed closer to the front in the D1 direction than the condenser lenses 365 to 368.

As described above, the optical module 3 includes the four drive circuits, the four laser beam emitting devices, the four collimating lenses, the four condenser lenses, and the fiber array, and is configured in such a way that laser beams propagate from the collimating lenses to the condenser lenses in free space. Consequently, it is possible to dispose the drive circuits 21 to 24 on the front surface 40a of the module substrate 10 between the collimating lenses 361 to 364 and the condenser lenses 365 to 368. Consequently, it is not necessary to form vias between the laser beam emitting devices 31 to 34 and the drive circuits 21 to 24, so that it is possible to suppress deterioration of a modulated signal due to the vias. Note that the numbers of the drive circuits, the laser beam emitting devices, and the condenser lenses are not limited to four, and may be one or may be a number equal to or more than two other than four.

Note that the optical module only needs to be configured to be able to transmit laser beams emitted from laser beam emitting devices to an external device or the like, and may include, for example, a PLC or a silicon photonics integrated circuit and be configured in such a way that the laser beams emitted from the laser beam emitting devices are input to this PLC or silicon photonics integrated circuit. In a case where the optical module is configured as described above, the optical module can be applied to the WDM system by using the PLC or the silicon photonics integrated circuit having a wavelength multiplexing function.

### Embodiment 4

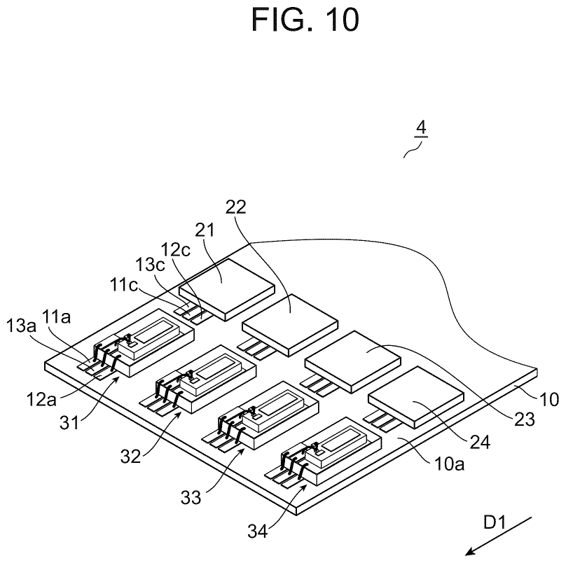

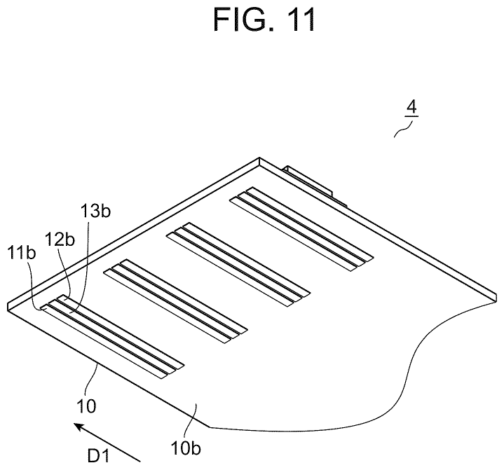

Next, an optical module 4 according to Embodiment 4 will be described with reference to FIGS. 10 and 11. Upon comparison between the optical module 4 according to Embodiment 4 and the optical module 1 according to Embodiment 1, wirings formed on the module substrate 10 and components related to arrangement of the drive circuits 21 to 24 are different, yet the other components are the same, and the same components as those in Embodiment 1 will be assigned the same reference numerals, and description thereof will be omitted.

FIG. 10 is a perspective view illustrating the optical module 4 according to Embodiment 4 and seen from the front surface 10a side, and FIG. 11 is a perspective view illustrating the optical module 4 according to Embodiment 4 and seen from the back surface 10b side. As illustrated in FIGS. 10 and 11, the optical module 4 includes the module substrate 10, the drive circuits 21 to 24, the laser beam emitting devices 31 to 34, wirings 11a, 12a, and 13a, wirings 11b, 12b, and 13b, and wirings 11c, 12c, and 13c. The drive circuits 21 to 24 are held on the front surface 10a of the module substrate 10 on which the laser beam emitting devices 31 to 34 are held, and are disposed closer to the rear (upstream) in the D1 direction than the laser beam emitting devices 31 to 34. Note that, since configurations of the drive circuits 22 to 24 and the laser beam emitting devices 32 to 34 of the optical module 4 are the same as the configurations of the drive circuit 21 and the laser beam emitting device 31, the configurations of the drive circuit 21 and the laser beam emitting device 31 will be described, and description of the configurations of the drive circuits 22 to 24 and the laser beam emitting devices 32 to 34 will be omitted.

The wirings 11c to 13c are formed on the front surface 10a of the module substrate 10, and are electrically connected with each terminal of the drive circuit 21. The wirings 11b to 13b are formed on the back surface 10b of the module substrate 10, and are electrically connected with the wirings 11c to 13c. The wirings 11a to 13a are formed on the front surface 10a of the module substrate 10, and are electrically connected with the wirings 11b to 13b and the laser beam emitting devices 31 to 34. For example, the wirings 11c to 13c and the wirings 11b to 13b are connected, and the wirings 11b to 13b and the wirings 11a to 13a are connected, by unillustrated vias formed along the upper/lower direction.

In a case where the optical module 4 according to Embodiment 4 is configured as described above, and includes, for example, an electrical connector closer to the upstream in the D1 direction than the drive circuits 21 to 24, the optical module 4 is configured in such a way that an input direction of electrical power from the electrical connector, a transmission direction of electrical signals from the drive circuits 21 to 24 to the laser beam emitting devices 31 to 34, and an emission direction of the laser beams from the laser beam emitting devices 31 to 34 are aligned, so that arrangement of each wiring is simplified, and it is possible to suppress design cost and miniaturize a product.

Note that the present disclosure enables free combinations of the embodiments, modification of arbitrary components in the embodiments, or omission of arbitrary components in the embodiments.

### INDUSTRIAL APPLICABILITY

The laser beam emitting devices according to the present disclosure can be used to convert electrical signals into optical signals when, for example, transmitting signals through optical fibers.

### REFERENCE SIGNS LIST

1: optical module, 3: optical module, 4: optical module, 10: module substrate (second substrate), 10a: front surface, 10b: back surface, 11: wiring, 11a: wiring, 11b: wiring, 11c: wiring, 12: wiring, 12a: wiring, 12b: wiring, 12c: wiring, 13: wiring, 13a: wiring, 13b: wiring, 13c: wiring, 14: wiring, 15: wiring, 16: wiring, 21: drive circuit (modulated signal output unit), 22: drive circuit (modulated signal output unit), 23: drive circuit (modulated signal output unit), 24: drive circuit (modulated signal output unit), 31: laser beam emitting device, 32: laser beam emitting device, 33: laser beam emitting device, 34: laser beam emitting device, 40: substrate (first substrate), 40a: front surface, 40b: back surface, 40c: side surface, 41: wiring, 43: wiring (signal line), 43a: specific transmission part, 44: wiring, 51: laser light source, 52: modulation unit, 61: condenser lens, 62: condenser lens, 63: condenser lens, 64: condenser lens, 70: fiber array, 71: optical system, 72: optical fiber, 231: laser beam emitting device, 241: wiring, 243: wiring (signal line), 243a: specific transmission part, 243b: specific transmission part, 361: collimating lens (parallel beam conversion unit), 362: collimating lens (parallel beam conversion unit), 363: collimating lens (parallel beam conversion unit), 364: collimating lens (parallel beam conversion unit), 365: condenser lens, 366: condenser lens, 367: condenser lens, 368: condenser lens, 370: fiber array, 371: optical system, D1: direction (predetermined direction), R1: terminating resistance, W1: wiring, W2: wiring, W3: wiring, W31: connection part, W4: wiring (wire), W41: connection part, W5: wiring

1. A laser beam emitting device comprising:
a modulator including a laser light source to generate a laser beam and a modulation device to modulate the laser beam generated by the laser light source and emit the laser beam toward one side of a predetermined direction;
a substrate to hold the modulator on a front surface of the substrate; and
a signal line to transmit a modulated signal for modulating the laser beam generated by the laser light source to the modulation device,
wherein the signal line is disposed at a position closer to the one end side than another end side of the substrate, and the modulated signal is input from the one end side, and the signal line is formed on a front side and a back side of the substrate continuously.

2. The laser beam emitting device according to claim 1, wherein the modulation device and the signal line are disposed closer to the one end side than a center of the substrate in the predetermined direction.

3. The laser beam emitting device according to claim 1, wherein the signal line is formed on the front surface of the substrate, a side surface of the substrate, and the back surface of the substrate continuously.

4. The laser beam emitting device according to claim 1, wherein the signal line includes a specific transmission part to transmit the modulated signal in a direction opposite to the predetermined direction.

5. The laser beam emitting device according to claim 1, further comprising a wire to connect the modulation device and the signal line,
wherein the signal line transmits the modulated signal to the modulation device via the wire.

6. An optical module comprising the laser beam emitting device according to claim 1,
wherein the substrate is a first substrate, and
the optical module includes:
a second substrate; and
a modulated signal output circuit to output the modulated signal for modulating the laser beam generated by the laser light source, the modulated signal output circuit being held on the second substrate,
wherein the laser beam emitting device is held on the second substrate.

7. The optical module according to claim 6, wherein the modulated signal output circuit is held on a surface opposite to a surface of the second substrate on which the laser beam emitting device is held.

8. The optical module according to claim 6, wherein the modulated signal output circuit is held on a surface of the second substrate on which the laser beam emitting device is held, and is disposed closer to a front, in the predetermined direction, than the laser beam emitting device. 9 The optical module according to claim 8, further comprising a parallel beam convertor to convert the laser beam emitted from the laser beam emitting device into a parallel beam, the parallel beam convertor being held on the surface of the second substrate on which the laser beam emitting device is held and being disposed closer to the front, in the predetermined direction, than the laser beam emitting device,
wherein the modulated signal output circuit is disposed closer to the front, in the predetermined direction, than the parallel beam convertor.

10. The optical module according to claim 6, wherein the modulated signal output circuit is held on a surface of the second substrate on which the laser beam emitting device is held, and is disposed closer to a rear, in the predetermined direction, than the laser beam emitting device.

11. The optical module according to claim 10, wherein the modulated signal output circuit is electrically connected with the laser beam emitting via a wiring, the wiring being formed on a surface opposite to the surface of the second substrate on which the laser beam emitting device is held.
